(19) United States
(12) Patent Application Publication
(10) Pub. No.: US 2014/0312315 A1
(43) Pub. Date: Oct. 23, 2014

(54) BACK PLANE OF FLAT PANEL DISPLAY AND METHOD OF MANUFACTURING THE SAME

(71) Applicant: Samsung Display Co., Ltd., Yongin-City (KR)

(72) Inventors: Il-Joon Kang, Yongin-City (KR); Young-Mi Cho, Yongin-City (KR); Tae-Young Kim, Yongin-City (KR); Kwang-Suk Kim, Yongin-City (KR)

(73) Assignee: SAMSUNG DISPLAY CO., LTD., Yongin-City (KR)

(21) Appl. No.: 14/011,700

(22) Filed: Aug. 27, 2013

(30) Foreign Application Priority Data
Apr. 18, 2013 (KR) 10-2013-0043026

(51) Int. Cl. H01L 29/786; H01L 51/56; H01L 29/66; H01L 27/32

(52) U.S. Cl. CPC H01L 29/7869; H01L 27/3244; H01L 51/56; H01L 29/66969
USPC 257/40; 438/23; 257/43

(57) ABSTRACT

According to an aspect of the present invention, there is provided a back plane for a flat-panel display device and a method of manufacturing the same. The back plane including: a substrate; a gate electrode on the substrate; a first insulation layer on the substrate and covering the gate electrode; a semiconductor layer on the first insulation layer and corresponding to the gate electrode; and a source electrode and a drain electrode on the semiconductor layer and electrically coupled to respective portions of the semiconductor layer. Here, the semiconductor layer includes indium, tin, zinc, and gallium, and an atomic concentration of the gallium is from about 5% to about 15%.

### CROSS-REFERENCE TO RELATED APPLICATION

This application claims priority to and the benefit of Korean Patent Application No. 10-2013-0043026, filed on Apr. 18, 2013, in the Korean Intellectual Property Office, the disclosure of which is incorporated herein in its entirety by reference.

### BACKGROUND

1. Field

The present invention relates to a back plane for a flat-panel display and a method of manufacturing the same.

2. Description of the Related Art

A flat-panel display device, such as an organic light emitting display device and a liquid crystal display device, is fabricated on a substrate on which a pattern including at least one thin-film transistor (TFT), a capacitor, and wiring for interconnecting the same is formed to drive the flat-panel display device. Here, the TFT includes an active layer, source/drain electrodes, and a gate electrode, which is electrically insulated from the active layer by a gate insulation layer.

An active layer of such a TFT may be formed of a semiconductor material, such as amorphous silicon or poly-silicon. When an active layer is formed of amorphous silicon, the active layer exhibits low mobility, and thus, it is difficult to provide a high-speed driving circuit. On the other hand, when an active layer is formed using poly-silicon, the active layer exhibits high mobility, but a threshold voltage of the active layer is not uniform. Therefore, a separate compensation circuit may be added to the active layer formed of a poly-silicon. Furthermore, because a conventional method of fabricating a TFT using low temperature poly-silicon (LTPS) includes expensive operations, such as laser heat treatment, costs regarding equipment investment and management are high, and it is difficult to apply the method to a large-scale substrate. To resolve the problems, research is being made on using oxide semiconductors as active layers.

Materials constituting oxide semiconductors include, for example, zinc oxides or materials containing zinc oxides. Fabrication of an oxide-based TFT may embody higher mobility compared to silicon-based semiconductors by using existing equipment for fabricating the silicon-based semiconductors. However, due to the mobility of threshold voltage due to environmental factors including light and temperature, reliability of the oxide-based TFT may be unsatisfactory.

### SUMMARY

Embodiments of the present invention provide a back plane for a flat-panel display including an oxide semiconductor thin-film transistor (TFT) and a method of manufacturing the same.

According to an aspect of the present invention, there is provided a back plane for a flat-panel display device, the back plane including: a substrate; a gate electrode on the substrate; a first insulation layer on the substrate and covering the gate electrode; a semiconductor layer on the first insulation layer and corresponding to the gate electrode; and a source electrode and a drain electrode on the semiconductor layer and electrically coupled to respective portions of the semiconductor layer. Here, the semiconductor layer includes indium, tin, zinc, and gallium, and an atomic concentration of the gallium is from about 5% to about 15%.

The semiconductor layer may be formed by using a target including an oxide of indium, tin, and zinc and gallium via sputtering.

The back plane may further include a third insulation layer on the first insulation layer and covering the source electrode and the drain electrode. Here, the third insulation layer may have a third hole exposing a portion of the source electrode or the drain electrode.

The semiconductor layer may include an oxide of indium, tin, and zinc.

The back plane may further include a second insulation layer on the first insulation layer, covering the semiconductor layer, and having a first hole and a second hole exposing portions of the semiconductor layer. Here, the source electrode and the drain electrode may be on the second insulation layer and may be in the first hole and the second hole, respectively.

The back plane may further include a third insulation layer on the first insulation layer and covering the source electrode and the drain electrode. Here, the third insulation layer may have a third hole exposing a portion of the source electrode or the drain electrode.

The back plane may further include: a pixel electrode on the third insulation layer, in the third hole, and electrically coupled to the source electrode or the drain electrode; an intermediate layer on the pixel electrode and including an organic emissive layer; and a counter electrode facing the pixel electrode across the intermediate layer.

The back plane may further include a fourth insulation layer on the third insulation layer, covering edges of the pixel electrode, and having an opening exposing at least a portion of the pixel electrode.

According to an aspect of the present invention, there is provided a method of manufacturing a back plane for a flat-panel display device, the method including: a first masking operation forming a gate electrode on a substrate; forming a first insulation layer on the substrate to cover the gate electrode; a second masking operation forming a semiconductor layer on the first insulation layer to correspond to the gate electrode; a third masking operation forming a second insulation layer having a first hole and a second hole exposing respective portions of the semiconductor layer, the second insulation layer covering the semiconductor layer and being on the first insulation layer; and a fourth masking operation forming a source electrode and a drain electrode on the semiconductor layer, the source electrode and the drain electrode being electrically coupled to the respective portions of the semiconductor layer. Here, the semiconductor layer includes indium, tin, zinc, and gallium, and an atomic concentration of the gallium is from about 5% to about 15%.

The semiconductor layer may be formed by using a target including an oxide of indium, tin, and zinc and gallium via sputtering.

The method may further include a fifth masking operation forming a third insulation layer on the first insulation layer covering the source electrode and the drain electrode and having a third hole exposing a portion of the source electrode or the drain electrode.

The semiconductor layer may include an oxide of indium, tin, and zinc.

The source electrode and the drain electrode may be formed on the second insulation layer and in the first hole and the second hole, respectively.

The method may further include a fifth masking operation forming a third insulation layer on the first insulation layer covering the source electrode and the drain electrode and having a third hole exposing a portion of the source electrode or the drain electrode.

The method may further include a sixth masking operation forming a pixel electrode on the third insulation layer and in the third hole, the pixel electrode being electrically coupled to the source electrode or the drain electrode.

The method may further include a seventh masking operation forming a fourth insulation layer on the third insulation layer covering edges of the pixel electrode and having an opening exposing at least a portion of the pixel electrode,

The method may further include: forming an intermediate layer on the pixel electrode, the intermediate layer including an organic emissive layer; and forming a counter electrode facing the pixel electrode across the intermediate layer.

According to another aspect of the present invention, there is provided a display device including: a substrate; and a semiconductor layer on the substrate, the semiconductor layer including indium, tin, zinc, and gallium. Here, an atomic concentration of the gallium is from about 5% to about 15%.

The semiconductor layer may include an oxide of indium, tin, and zinc.

The display device may further include a transistor on the substrate, the transistor including the semiconductor layer.

### BRIEF DESCRIPTION OF THE DRAWINGS

The above and other features and aspects of the present invention will become more apparent by describing in detail exemplary embodiments thereof with reference to the attached drawings, in which:

FIG. 1 is a schematic cross-sectional view of a back plane for a flat-panel display device according to an embodiment of the present invention;

FIGS. 2 through 4 and 6(b) through 10 are schematic cross-sectional diagrams showing a process for manufacturing a back plane for a flat-panel display device according to an embodiment of the present invention;

FIGS. 5 and 6(a) are schematic cross-sectional diagrams showing a process for manufacturing a back plane for a flat-panel display device according to another embodiment of the present invention; and

FIGS. 11-13 are graphs showing characteristics of the semiconductor layer 22 according to Ga concentration.

### DETAILED DESCRIPTION

The present inventive concept will now will now be described more fully with reference to the accompanying drawings, in which example embodiments of the present inventive concept are shown.

As the present invention allows for various changes and numerous embodiments, example embodiments will be illustrated in the drawings and described in detail in the description. However, this is not intended to limit the present invention to a particular mode of practice, and it is to be appreciated that the present invention encompasses all changes, equivalents, and substitutes that do not depart from the spirit and technical scope thereof. In the description of the present invention, well-known methods will not be described in detail so as not to unnecessarily obscure features of the present invention.

While the terms such as “first” and “second” may be used to describe various components, such components must not be limited to the above terms. The terms are used only to distinguish one component from another. As used herein, the term “and/or” includes any and all combinations of one or more of the associated listed items. Also, expressions such as “at least one of,” when preceding a list of elements, modify the entire list of elements and do not modify the individual elements of the list.

The terms used in the present application are merely used to describe an embodiment, and are not intended to limit the present invention. Use of singular forms includes plural references as well unless expressly specified otherwise. The terms “comprising”, “including”, and “having” specify the presence of stated features, numbers, steps, operations, elements, components, and/or a combination thereof but do not preclude the presence or addition of one or more other features, numbers, steps, operations, elements, components, and/or a combination thereof. When an element is referred to as being “on” or “coupled to” (e.g., electrically coupled or connected to) another element, the element may be directly “on” or “coupled to” the other element or one or more intervening elements may be interposed therebetween.

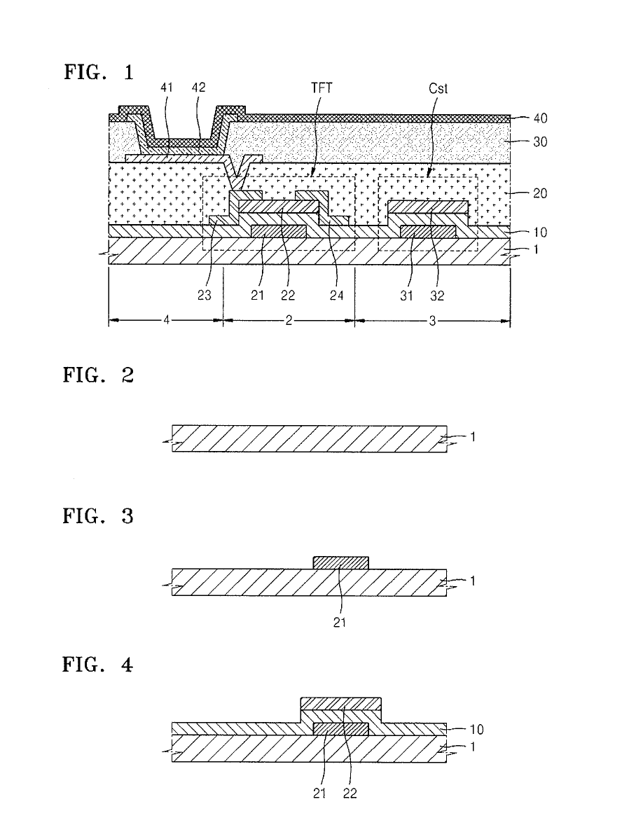

FIG. 1 is a schematic cross-sectional view of a back plane for a flat-panel display device according to an embodiment of the present invention. Referring to FIG. 1, the back plane for a flat-panel display device includes a transistor region 2, a storage region 3, and an emissive region 4. If a flat-panel display device is a top-emission type, the transistor region 2 and the emissive region 4 may overlap each other.

In the transistor region 2, a thin-film transistor (TFT) is arranged as a driving device. The TFT includes a gate electrode 21, an active layer 22, and source and drain electrodes 23 and 24. The TFT according to an embodiment of the present invention may be a bottom-gate type in which the gate electrode 21 is arranged below the active layer 22, or a top-contact type in which the source electrode 24 and the drain electrode 23 contact the top of the active layer 22. Furthermore, material-wise, the TFT may be an oxide semiconductor TFT in which the active layer 22 includes an oxide semiconductor.

A capacitor Cst is arranged in the storage region 3. The capacitor Cst includes a bottom electrode 31 and a top electrode 32, where a first insulation layer 10 is interposed therebetween. Here, the bottom electrode 31 may be formed on the same layer and of the same material as the gate electrode 21 of the TFT. The top electrode 32 may be formed on the same layer and of the same material as the source and drain electrodes 23 and 24 of the TFT.

An organic light emitting device EL is arranged in the emissive region 4. The organic light emitting device EL includes a pixel electrode 41 coupled to either the source electrode 24 or the drain electrode 23 of the TFT, a counter electrode 40 arranged to face the pixel electrode 41, and an intermediate layer 42, which is interposed between the pixel electrode 41 and the counter electrode 40 and includes an organic emissive layer.

According to an embodiment of the present invention, because the emissive region 4 includes the organic light emitting device EL, the back plane shown in FIG. 1 may be used as a back plane for an organic light emitting display device. However, the present invention is not limited thereto. For example, if liquid crystals are arranged between the pixel electrode 41 and the counter electrode 40, the back plane shown in FIG. 1 may be used as a back plane for a liquid crystal display device.

FIGS. 2 through 10 are schematic cross-sectional diagrams showing a process for manufacturing a back plane for a flat-panel display device according to embodiments of the present invention.

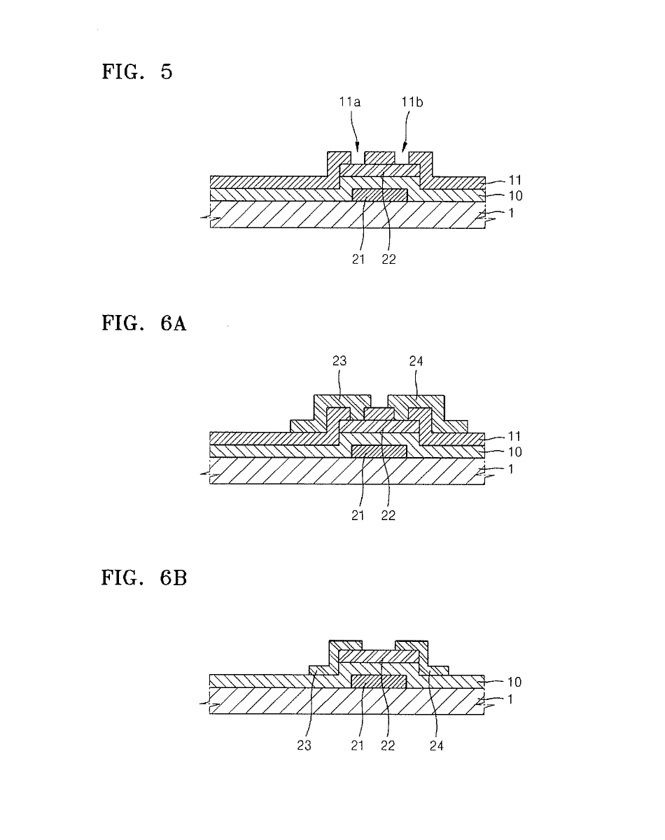

In detail, FIGS. 2 through 4 and FIGS. 6(b) through 10 are schematic cross-sectional diagrams showing a process for manufacturing the back plane for a flat-panel display device as shown in FIG. 1; whereas, FIGS. 5 and 6(a) are schematic cross-sectional diagrams showing a process for manufacturing a back plane for a flat-panel display device according to another embodiment of the present invention.

Hereinafter, the process for manufacturing a back plane for a flat-panel display device will be described in detail by focusing on the transistor region 2 and the emissive region 4, and detailed descriptions of a process for manufacturing the storage region 3 will be omitted.

First, as shown in FIG. 2, a substrate 1 is provided. The substrate 1 may be formed of, for example, a transparent SiO₂-based glass material. However, because a flat-panel display device according to an embodiment of the present invention may be a top-emission type, materials for forming the substrate 1 are not limited thereto. For example, the substrate 1 may be formed of any of a variety of non-transparent materials, e.g., plastics, metals, etc. Also, the substrate 1 may be formed of a flexible plastic film or a thin-film glass, such that a flat-panel display may be bent or folded.

A barrier layer, a blocking layer, and/or an auxiliary layer (not shown) (e.g., a buffer layer) may be provided on the top surface of the substrate 1 to prevent diffusion of impurity ions, to prevent permeation of moisture or outside atmosphere, and to planarize the top surface of the substrate 1.

The auxiliary layer may be formed of a silicon oxide (SiO₂) and/or a silicon nitride (SiNₓ) by using any of a variety of deposition methods, such as plasma enhanced chemical vapor deposition (PECVD), atmospheric pressure CVD (APCVD), and low pressure CVD (LPCVD).

Next, as shown in FIG. 3, the gate electrode 21 is formed on the substrate 1. The gate electrode 21 may be patterned in a masking operation using a first mask (not shown). The first masking operation using the first mask may be performed by using any of a variety of methods including wet etching and dry etching.

The gate electrode 21 may contain one or more materials selected from among silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), molybdenum-tungsten (MoW), or copper (Cu). However, the present invention is not limited thereto, and the gate electrode 21 may be formed of other conductive materials, including metals.

The first masking operation as described above forms the gate electrode 21 on the substrate 1.

Referring to FIG. 4, the first insulation layer 10 is deposited on the structure shown in FIG. 3, which is a resulting structure of the first masking operation, and the semiconductor layer 22 may be pattern-formed thereon. A second masking operation, as described above, may form the first insulation layer 10 to cover the gate electrode 21 and to form the semiconductor layer 22 on the first insulation layer 10 in correspondence to the gate electrode 21.

The first insulation layer 10 may be formed of an inorganic insulation layer containing SiNₓ or SiOₓ by using PECVD, APCVD, or LPCVD. A portion of the first insulation layer 10 may be interposed between the semiconductor layer 22 and the gate electrode 21 of the transistor region 2, and may function as a gate insulation layer of the transistor region 2. Furthermore, although not shown in FIG. 4, a portion of the first insulation layer 10 may be interposed between the bottom electrode 31 and the top electrode 32 of the capacitor Cst in the storage region 3, and may function as a dielectric layer of the capacitor Cst.

Although formation of the semiconductor layer 22 is not shown, the semiconductor layer 22 may be formed by depositing a conductive layer, a photosensitive film thereon, aligning a second mask (not shown) to the first insulation layer 10, exposing the photosensitive film by irradiating light in a predetermined wavelength band thereto, and etching the conductive layer other than the semiconductor layer 22 by using the patterned photosensitive film as an etch stopper.

The semiconductor layer 22 may include an oxide semiconductor. For example, the semiconductor layer 22 may include an oxide of a material selected from among Group XII, Group XIII, and Group XIV metal atoms including zinc (Zn), indium (In), gallium (Ga), tin (Sn), cadmium (Cd), germanium (Ge), and hafnium (Hf) and combinations thereof. For example, the semiconductor layer 22 may contain Ga—Sn—In—Zn—O. The Sn addition may increase mobility of the semiconductor layer 22.

The second masking operation may form the semiconductor layer 22 by using a target including an oxide of In, Zn, and Sn and Ga via sputtering.

Sputtering is an operation in which a target material is formed from a sputtering target having a uniform thickness in correspondence to a magnetic field generated by a magnet unit and the target material is deposited onto a substrate and forms a thin film.

As stated above, fabrication of an oxide-based TFT may embody higher mobility compared to silicon-based semiconductors and may use existing equipment (e.g., equipment for fabricating the silicon-based semiconductors). However, due to a mobility of a threshold voltage due to environmental factors, including light and temperature, reliability of the oxide-based TFT may be unsatisfactory.

Reasons for the mobility of the threshold voltage may include internal defects, such as oxygen vacancy formed in a material used in the semiconductor layer 22, and permeation of the outside atmosphere, e.g., hydrogen, moisture. To prevent such defects, the semiconductor layer 22 may be protected by using an etch stop layer (ESL), or device reliability may be secured by adjusting operation conditions, such as oxygen partial pressure, heat treatment temperature, and sputtering voltage. However, more fundamentally, device reliability may be secured by changing materials used in the semiconductor layer 22.

According to an embodiment of the present invention, the semiconductor layer 22 may include an In—Sn—Zn—O (ITZO) material and may further include Ga. Here, the atomic concentration of Ga may be from about 5% to about 15%. When Ga is contained in the ratio as stated above, carrier mobility of the semiconductor layer 22 is maintained at an appropriate level, and reliability of the TFT including the semiconductor layer 22 is improved. As used herein, Ga concentration is an atomic concentration.

If Ga concentration is smaller than about 5%, hole mobility and carrier mobility of the semiconductor layer 22 vary according to oxygen partial pressure during fabrication. Even a small variation of oxygen partial pressure changes hole mobility and carrier mobility. Therefore, hole mobility and carrier mobility significantly vary according to environmental changes, and hole mobility and carrier mobility of the semiconductor layer 22 become non-uniform. As a result, reliability of the TFT is deteriorated.

As the Ga concentration increases, hole mobility and carrier mobility become less sensitive to oxygen partial pressure during fabrication. As a result, hole mobility of the semiconductor layer 22 becomes uniform, and thus, reliability of the TFT is improved.

However, if Ga concentration exceeds about 15%, regardless of the uniformity of hole mobility, electron effective mass of the semiconductor layer 22 increases, thereby reducing hole mobility. Therefore, it may become difficult to embody a high-performance device.

Accordingly, in embodiments of the present invention, Ga concentration may be from about 5% to about 15%. When the semiconductor layer 22 contains Ga at a concentration within this range, the semiconductor layer 22 may secure a sufficient hole mobility and may retain uniform device characteristics even if the fabrication environment slightly varies. Therefore, device reliability may be secured.

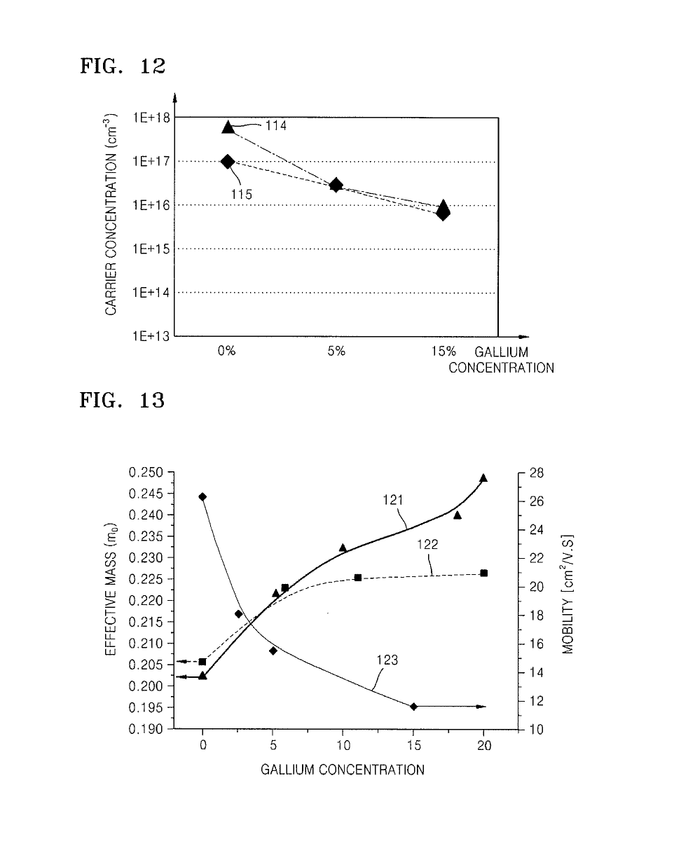

Data will be given below with reference to FIGS. 11 and 12 regarding characteristics of the semiconductor layer 22 according to Ga concentration.

Referring now to FIG. 5, a second insulation layer 11 may be deposited on the structure of FIG. 4, which is a resulting structure of the second masking operation, and may be patterned. In detail, the second insulation layer 11 is deposited on the structure of FIG. 4, and a portion of the second insulation layer 11 is etched for forming a first hole 11a and a second hole 11b that expose portions of the semiconductor layer 22. The second insulation layer 11 may protect the semiconductor layer 22. The first hole 11a and the second hole 11b may be formed by using any of a variety of methods, including wet etching and dry etching, as long as portions of the semiconductor layer 22 therebelow are not etched.

A third masking operation, as described above, forms the second insulation layer 11, which includes the first hole 11a and the second hole 11b exposing portions of the semiconductor layer 22 and which covers the semiconductor layer 22, on the first insulation layer 10. The third masking operation may be performed for protecting the semiconductor layer 22, and thus, may be omitted to simplify the overall process.

Referring to FIG. 6(a), the source electrode 24 and the drain electrode 23 may be pattern-formed on the structure of FIG. 5, which is a resulting structure of the third masking operation. Referring to FIG. 6(a), the source electrode 24 and the drain electrode 23 may be formed on the second insulation layer 11 and may fill the first hole 11a and the second hole 11b.

FIG. 6(b) shows that, when the third masking operation is omitted, the source electrode 24 and the drain electrode 23 are pattern-formed on the structure of FIG. 4, which is a resulting structure of the second masking operation. Referring to FIG. 6(b), the source electrode 24 and the drain electrode 23 are formed on the first insulation layer 10, and the source electrode 24 and the drain electrode 23 may contact potions of the semiconductor layer 22, respectively.

The source electrode 24 and the drain electrode 23 may contain one or more materials selected from among silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), molybdenum (Mo), titanium (Ti), tungsten (W), molybdenum-tungsten (MoW), or copper (Cu). However, the present invention is not limited thereto, and the source electrode 24 and the drain electrode 23 may be formed of any of a variety of conductive materials, including metals.

A fourth masking operation, as described above, forms the source electrode 24 and the drain electrode 23, which contact portions of the semiconductor layer 22, on the second insulation layer 11. Later operations will be described based on FIG. 6(b) corresponding to the case in which the formation of the second insulation layer 11 is omitted.

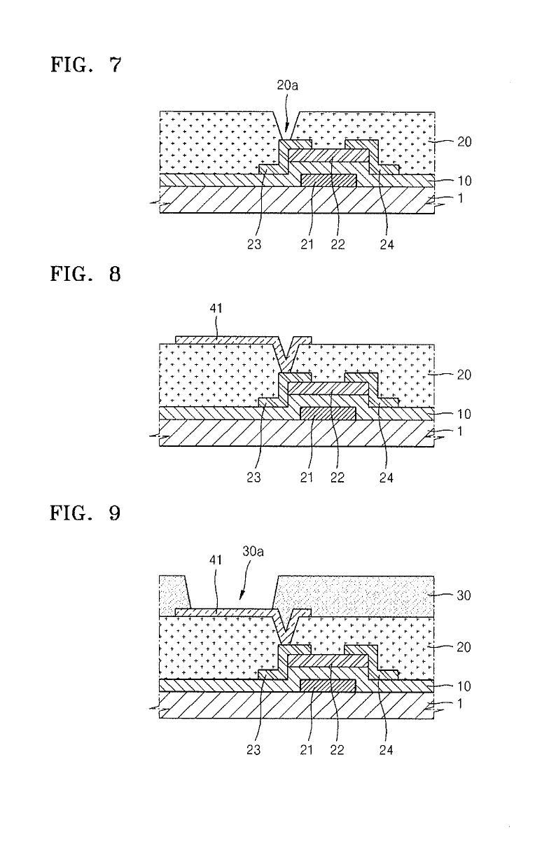

Referring now to FIG. 7, a third insulation layer 20, in which a third hole 20a exposing a portion of the source electrode 24 or the drain electrode 23 is formed. The third insulation layer 20 may be formed on the structure of FIG. 6(b), which is a resulting structure of the fourth masking operation.

The third hole 20a may be pattern-formed in a masking operation using a fifth mask (not shown). The third hole 20a may be formed to electrically connect a pixel electrode, described below, and the TFT in the transistor region 2. Although FIG. 7 shows that the third hole 20a is formed to expose the drain electrode 23, the present invention is not limited thereto; for example, the third hole 20a may be formed to expose the source electrode 24. Furthermore, a shape and location of the third hole 20a are not limited to what is shown in FIG. 7.

The third insulation layer 20 may be formed of one or more organic insulation materials selected from a group consisting of polyimide, polyamide, acrylic resins, benzocyclobutene, and phenol resins by using a method like spin coating. However, the third insulation layer 20 may not only be formed of organic insulation materials as stated above, but also may be formed of inorganic materials selected from among SiO₂, SiNx, Al₂O₃, CuOx, Tb₄O₇, Y₂O₃, Nb₂O₅, and Pr₂O₃. Furthermore, the third insulation layer 20 may have a multi-layer structure in which organic insulation materials and inorganic insulation materials are alternately stacked.

The third insulation layer 20 is formed to have a sufficient thickness, e.g., a thickness greater than that of the first insulation layer 10 or the second insulation layer 11, and may function as a planarizing layer for planarizing the surface on which pixel electrodes described below will be formed, or may function as a passivation layer for protecting the drain electrode 23 and the source electrode 24 in the transistor region 2.

A fifth masking operation, as described above, forms the third insulation layer 20 (in which the third hole 20a exposing a portion of the source electrode 24 or the drain electrode 23 is formed) on the first insulation layer 10 to cover the source electrode 24 and the drain electrode 23. If the second insulation layer 11 is formed in the fourth masking operation, the third insulation layer 20 may be formed on the second insulation layer 11.

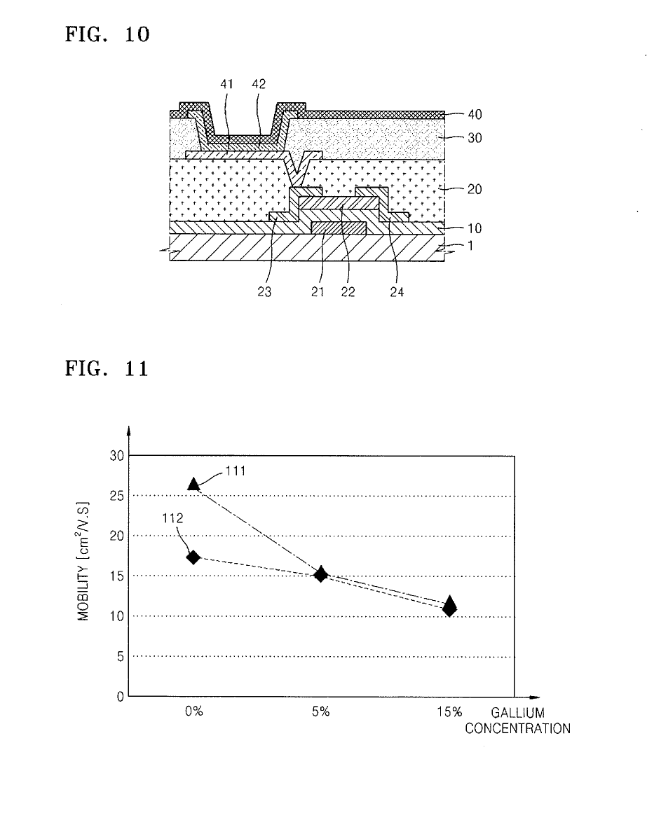

Referring now to FIG. 8, the pixel electrode 41 may be formed on the structure of FIG. 7, which is a resulting structure of the fifth masking operation. The pixel electrode 41 may be formed on the third insulation layer 20 and may be electrically connected to either the source electrode 24 or the drain electrode 23. The pixel electrode 41 may fill the third hole 20a of the third insulation layer 20 and may be electrically connected to the portion of the source electrode 24 or the drain electrode 23 that is exposed by the third hole 20a. The pixel electrode 41 may be pattern-formed in a masking operation using a sixth mask (not shown).

The pixel electrode 41 may be coupled to either the source electrode 24 or the drain electrode 23 via the third hole 20a. The pixel electrode 41 may be formed of any of a variety of materials according to an emission type of an organic light emitting display device. For example, if the organic light emitting display device is a bottom-emission type (in which an image is formed toward the substrate 1) or a dual-emission type (in which an image is formed both toward the substrate 1 and in a direction opposite thereto), the pixel electrode 41 may be formed of a transparent metal oxide. The pixel electrode 41 may include one or more materials from among materials including ITO, IZO, ZnO, and In₂O₃. In this case, although not shown, the pixel electrode 41 may be designed to not to overlap the transistor region 2 and the storage region 3.

However, if the organic light emitting display device is a top-emission type (in which an image is formed in a direction away from the substrate 1), the pixel electrode 41 may further include a reflective electrode formed of a material for reflecting light. In this case, the pixel electrode 41 may be designed to partially overlap the transistor region 2 as shown in FIG. 8.

A sixth masking operation, as described above, forms a pixel electrode 41, which fills the third hole 20a and is electrically connected to the portion of the source electrode 24 or the drain electrode 23, on the third insulation layer 20.

Referring now to FIG. 9, a fourth insulation layer 30 may be formed on the structure of FIG. 8, which is a resulting structure of the sixth masking operation. The fourth insulation layer 30 may be formed to cover edges of the pixel electrode 41 and may include an opening 30a exposing at least a portion of the pixel electrode 41. The fourth insulation layer 30 may be pattern-formed in a masking operation using a seventh mask (not shown).

Referring now to FIG. 10, the intermediate layer 42 and the counter electrode 40 may be formed on the structure of FIG. 9, which is a resulting structure of a seventh masking operation. For example, an eighth masking operation may form the intermediate layer 42 including an organic light-emitting layer on the portion of the pixel electrode 41 exposed by the opening 30a and may form the counter electrode 40 to face the pixel electrode 41 across the intermediate layer 42.

The intermediate layer 42 may be formed as one or more functional layers from among an organic emissive layer (EML), a hole transport layer (HTL), a hole injection layer (HIL), and an electron injection layer (EIL). The intermediate layer 42 may be stacked in a single-layer structure or a composite structure. The intermediate layer 42 may be formed of an organic monomer material or an organic polymer material.

If the intermediate layer 42 is formed of an organic monomer material, a HTL and a HIL are stacked from an EML toward the pixel electrode 41, whereas an ETL and an EIL are stacked from the EML toward the counter electrode 40. Here, the organic materials may include copper phthalocyanine (CuPC), N,N′-Di(naphthalene-1-yl)-N,N′-diphenyl-benzidine (NPB), tris-8-hydroxyquinoline aluminum (Alq3), etc.

If, however, the intermediate layer 42 is formed of an organic polymer material, only a HTL may be formed from an EML toward the pixel electrode 41. The HTL may be formed on the top of the pixel electrode 41 using poly-(2,4)-ethylene-dihydroxy thiophene (PEDOT) or polyaniline (PANI) via a method including inkjet printing and spin coating. Here, the organic materials may include poly-phenylenevinylene (PPV)-based organic polymer materials or polyfluorene-based organic polymer material, and a color pattern may be formed via a common method, including inkjet printing, spin coating, or laser thermal transfer.

The EML may form a unit pixel including sub-pixels emitting red, green, and blue lights.

The counter electrode 40 may be deposited onto the entire substrate 1 and be formed as a common electrode. In the case of the organic light emitting display device according to the present embodiment, the pixel electrode 41 may be used as an anode, whereas the counter electrode 40 may be used as a cathode, or vice versa.

In the embodiment described above, the intermediate layer 42 is formed in the opening 30a, and light-emitting materials are independently formed in respective pixels. However, the present invention is not limited thereto. For example, the intermediate layer 42 may be formed throughout the fourth insulation layer 30 regardless of locations of pixels.

For example, the intermediate layer 42 may be formed as emissive layers, including emissive materials emitting red light, green light, and blue light, and may be stacked in a vertical direction or mixed. Other color combinations are possible, for example, when white light is emitted. Furthermore, a color converting layer or a color filter for converting the emitted white light to light of a predetermined color may be further arranged.

If the organic light emitting display device is a top-emission type (in which an image is formed in a direction away from the substrate 1), the counter electrode 40 is a transparent electrode and the pixel electrode 41 is a reflective electrode. Here, the reflective electrode may be formed by depositing a metal having a small work function, e.g., Ag, Mg, Al, Pt, Pd, Au, Ni, Nd, Ir, Cr, Li, Ca, LiF, or a compound thereof, to have a small thickness. In a back plane for a flat-panel display device according to an embodiment of the present invention, the counter electrode 40 may be formed as a phototransmissive electrode.

In the masking operations for forming the organic light emitting display device, stacked layers may be removed via dry etching or wet etching. Furthermore, although each of the attached drawings for describing embodiments of the present invention shows one transistor and one capacitor for convenience of explanation, the present invention is not limited thereto, and a plurality of TFTs and a plurality of capacitors may be included. According to an embodiment of the present invention, including a plurality of TFTs and a plurality of capacitors does not increase the number of masking operations.

FIGS. 11-12 are graphs showing characteristics of the semiconductor layer 22 according to Ga concentration. FIG. 11 shows graphs illustrating hole mobility characteristics of the semiconductor layer 22 according to Ga concentration, whereas FIG. 12 shows graphs illustrating carrier concentration characteristics of the semiconductor layer 22 according to Ga concentration. Hereinafter, Ga concentration is atomic concentration.

First, referring to FIG. 11, a graph 111 corresponds to a case in which oxygen partial pressure is 0% during fabrication of the semiconductor layer 22, whereas a graph 112 corresponds to a case in which oxygen partial pressure is 5% during fabrication of the semiconductor layer 22. Hole mobilities of the semiconductor layer 22 corresponding to different Ga concentrations are shown.

Referring to FIG. 11, when a target for forming the semiconductor layer 22 contains Ga at 0% concentration, hole mobility of the semiconductor layer 22 varies significantly according to oxygen partial pressure during the fabrication of the semiconductor layer 22. However, when the target for forming the semiconductor layer 22 contains Ga at about 5% or higher concentration, hole mobility of the semiconductor layer 22 is constant (or substantially constant) even if oxygen partial pressure varies during the fabrication of the semiconductor layer 22. Therefore, because hole mobility of the semiconductor layer 22 is constant even if oxygen partial pressure varies during the fabrication of the semiconductor layer 22, device reliability is improved.

Referring to FIG. 12, a graph 114 corresponds to a case in which oxygen partial pressure is 0% during fabrication of the semiconductor layer 22, whereas a graph 115 corresponds to a case in which oxygen partial pressure is about 5% during fabrication of the semiconductor layer 22. Carrier concentrations of the semiconductor layer 22 corresponding to different Ga concentrations are shown.

Referring to FIG. 12, when a target for forming the semiconductor layer 22 contains Ga at 0% concentration, carrier concentration of the semiconductor layer 22 varies significantly according to oxygen partial pressure during the fabrication of the semiconductor layer 22. However, when the target for forming the semiconductor layer 22 contains Ga at about 5% or higher concentration, carrier concentration of the semiconductor layer 22 is constant (or substantially constant) even if oxygen partial pressure varies during the fabrication of the semiconductor layer 22. Therefore, because carrier concentration of the semiconductor layer 22 is constant even if oxygen partial pressure varies during the fabrication of the semiconductor layer 22, device reliability is improved.

FIG. 13 is a graph showing another characteristic according to Ga concentrations. In detail, FIG. 13 shows electron effective mass and hole mobility according to Ga concentrations. In FIG. 13, a graph 121 shows electron effective mass of the semiconductor layer 22 according to Ga concentration when composition ratio among tin, indium, and zinc is 2:1:3, a graph 122 shows electron effective mass of the semiconductor layer 22 according to Ga concentration when composition ratio among tin, indium, and zinc is 2:3:3, and a graph 123 shows hole mobility of the semiconductor layer 22 according to Ga concentration when composition ratio among tin, indium, and zinc is 2:3:3.

Electron effective mass may be calculated according to Equation 1 below. Equation 1:

$$μ = \frac{τ}{{m}^{*}}$$

Here, μ may denote mobility, m* may denote electron effective mass, and τ may denote average electron scattering time. Electron effective masses according to respective Ga concentrations may be calculated in a simulation, and mobility may be induced by applying the calculated electron effective masses to Equation 1.

Referring to FIG. 13, the graph 121 shows that electron effective mass continuously increases as Ga concentration increases, and thus, mobility continuously increases. However, the graph 122 shows that electron effective mass reaches a predetermined limit value as Ga concentration increases, and the graph 123 shows that hole mobility decreases as Ga concentration increases.

Referring to FIG. 13, although hole mobility decreases as Ga concentration increases, in an embodiment of the present invention, a suitable (or sufficient) hole mobility may be secured as long as Ga concentration does not exceed about 15%.

Table 1 below shows a result of a simulation regarding electron effective masses according to Ga concentration in ITZO.

TABLE 1

| Ga Concentration(%) | Electron Effective Mass |
|---|---|
| 0.00 | 0.202032 |
| 5.26 | 0.221621 |
| 10.00 | 0.232344 |
| 15.00 | 0.234126 |
| 18.18 | 0.240074 |

Referring to the result of the simulation, it is clear that electron effective mass increases as Ga concentration increases, thereby reducing mobility. When the result of the simulation as shown in Table 1 is reflected to Equation 1, mobilities in the respective cases may be calculated.

According to the report Amorphous Oxide Semiconductors for High-Performance Flexible Thin-Film Transistors (Journal: Jpn. J. Appl. Phys., 45, 4303 (2006), Author: Hideo Hosono), the entire content of which is incorporated herein by reference, the minimum mobility of an amorphous oxide for embodying a high-performance device is at least 10 cm².V⁻¹.s⁻¹.

However, referring to Table 1 and Equation 1, mobility is 10 cm². V⁻¹.s⁻¹ when Ga concentration is 15%. According to the result of the simulation shown in Table 1, mobility decreases as electron effective mass increases as Ga concentration increases, and thus, it is difficult to guarantee the mobility of 10 cm².V⁻¹.s⁻¹ when Ga concentration exceeds 15%.

Therefore, when Ga concentration of a sputtering target for forming the semiconductor layer 22 is set to from about 5% to about 15%, and thus, Ga concentration of the semiconductor layer 22 is set to from about 5% to about 15%, suitable (or sufficient) hole mobility for embodying a hih-performance device may be maintained and reliability of a TFT may be secured.

According to embodiments of the present invention, an organic light emitting display apparatus includes an oxide semiconductor layer including an oxide of indium, tin, and zinc and gallium, thereby exhibiting high mobility and stable electric characteristics. For example, as the oxide semiconductor layer containing an oxide of indium, tin, and zinc and gallium contains gallium at an atomic concentration from about 5% to about 15%, 10 cm².V⁻.s⁻¹ or higher mobility may be secured. Furthermore, device characteristics do not vary significantly according to environmental variables during fabrication, and thus, reliability of a TFT may be secured.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A back plane for a flat-panel display device, the back plane comprising:
a substrate;
a gate electrode on the substrate;
a first insulation layer on the substrate and covering the gate electrode;
a semiconductor layer on the first insulation layer and corresponding to the gate electrode; and
a source electrode and a drain electrode on the semiconductor layer and electrically coupled to respective portions of the semiconductor layer,
wherein the semiconductor layer comprises indium, tin, zinc, and gallium, and
wherein an atomic concentration of the gallium is from about 5% to about 15%.

2. The back plane of claim 1, wherein the semiconductor layer is formed by using a target comprising an oxide of indium, tin, and zinc and gallium via sputtering.

3. The back plane of claim 1, further comprising a third insulation layer on the first insulation layer and covering the source electrode and the drain electrode,
wherein the third insulation layer has a third hole exposing a portion of the source electrode or the drain electrode.

4. The back plane of claim 3, further comprising:
a pixel electrode on the third insulation layer, in the third hole, and electrically coupled to the source electrode or the drain electrode;
an intermediate layer on the pixel electrode and comprising an organic emissive layer; and
a counter electrode facing the pixel electrode across the intermediate layer.

5. The back plane of claim 4, further comprising a fourth insulation layer on the third insulation layer, covering edges of the pixel electrode, and having an opening exposing at least a portion of the pixel electrode.

6. The back plane of claim 1, wherein the semiconductor layer comprises an oxide of indium, tin, and zinc.

7. The back plane of claim 1, further comprising a second insulation layer on the first insulation layer, covering the semiconductor layer, and having a first hole and a second hole exposing portions of the semiconductor layer,
wherein the source electrode and the drain electrode are on the second insulation layer and are in the first hole and the second hole, respectively.

8. A method of manufacturing a back plane for a flat-panel display device, the method comprising:
a first masking operation forming a gate electrode on a substrate;
forming a first insulation layer on the substrate to cover the gate electrode;
a second masking operation forming a semiconductor layer on the first insulation layer to correspond to the gate electrode;
a third masking operation forming a second insulation layer having a first hole and a second hole exposing respective portions of the semiconductor layer, the second insulation layer covering the semiconductor layer and being on the first insulation layer; and
a fourth masking operation forming a source electrode and a drain electrode on the semiconductor layer, the source electrode and the drain electrode being electrically coupled to the respective portions of the semiconductor layer,
wherein the semiconductor layer comprises indium, tin, zinc, and gallium, and
wherein an atomic concentration of the gallium is from about 5% to about 15%.

9. The method of claim 8, wherein the semiconductor layer is formed by using a target comprising an oxide of indium, tin, and zinc and gallium via sputtering.

10. The method of claim 8, further comprising a fifth masking operation forming a third insulation layer on the first insulation layer covering the source electrode and the drain electrode and having a third hole exposing a portion of the source electrode or the drain electrode.

11. The method of claim 10, further comprising a sixth masking operation forming a pixel electrode on the third insulation layer and in the third hole, the pixel electrode being electrically coupled to the source electrode or the drain electrode.

12. The method of claim 11, further comprising a seventh masking operation forming a fourth insulation layer on the third insulation layer covering edges of the pixel electrode and having an opening exposing at least a portion of the pixel electrode,

13. The method of claim 8, wherein the semiconductor layer comprises an oxide of indium, tin, and zinc.

14. The method of claim 8, wherein the source electrode and the drain electrode are formed on the second insulation layer and in the first hole and the second hole, respectively.

15. The method of claim 14, further comprising:
forming an intermediate layer on the pixel electrode, the intermediate layer comprising an organic emissive layer; and
forming a counter electrode facing the pixel electrode across the intermediate layer.

16. A display device comprising:
a substrate; and
a semiconductor layer on the substrate, the semiconductor layer comprising indium, tin, zinc, and gallium,
wherein an atomic concentration of the gallium is from about 5% to about 15%.

17. The display device of claim 16, wherein the semiconductor layer comprises an oxide of indium, tin, and zinc.

18. The display device of claim 17, further comprising a transistor on the substrate, the transistor comprising the semiconductor layer.
